(19) United States
(12) Patent Application Publication
(10) Pub. No.: US 2012/0241972 A1
(43) Pub. Date: Sep. 27, 2012

(54) LAYOUT SCHEME FOR AN INPUT OUTPUT CELL

(75) Inventors: Yu-Ren CHEN, Hsinchu City (TW); Kuo-Ji CHEN, Taipei County (TW); Guang-Cheng WANG, Zhubei City (TW)

(73) Assignee: TAIWAN SEMICONDUCTOR MANUFACTURING COMPANY, LTD., Hsinchu (TW)

(21) Appl. No.: 13/070,772

(22) Filed: Mar. 24, 2011

(51) Int. Cl. H01L 23/50; H01L 21/441

(52) U.S. Cl. 257/774; 438/667; 257/E23.079; 257/E21.477

(57) ABSTRACT

An integrated circuit layout for an Input Output (IO) cell includes at least three metal layers. An IO pad is disposed directly over a top metal layer of the at least three metal layers. At least top two metal layers of the at least three metal layers provide a power bus and a ground bus.

### TECHNICAL FIELD

The present disclosure relates generally to an integrated circuit, and more particularly to an Input Output (IO) cell.

### BACKGROUND

In an integrated circuit, an Input Output (IO) pad is used for an electrical connection of an IO cell by wire bonding and packaging. In a conventional layout, the IO pad is provided on top of additional protective metal layers (e.g., to avoid breaking the IO pad from wire bonding) formed over power/ground bus metal layers. With more metal layers, more masks are needed for fabrication, which results in a higher cost.

### BRIEF DESCRIPTION OF THE DRAWINGS

Reference is now made to the following descriptions taken in conjunction with the accompanying drawings, in which:

FIG. 1 is a schematic diagram showing an exemplary integrated circuit layout for an IO cell according to some embodiments; and

FIG. 2 is a flowchart for a method of forming an IO cell for the exemplary integrated circuit layout in FIG. 1 according to some embodiments.

### DETAILED DESCRIPTION

The making and using of various embodiments are discussed in detail below. It should be appreciated, however, that the present disclosure provides many applicable inventive concepts that can be embodied in a wide variety of specific contexts. The specific embodiments discussed are merely illustrative of specific ways to make and use, and do not limit the scope of the disclosure.

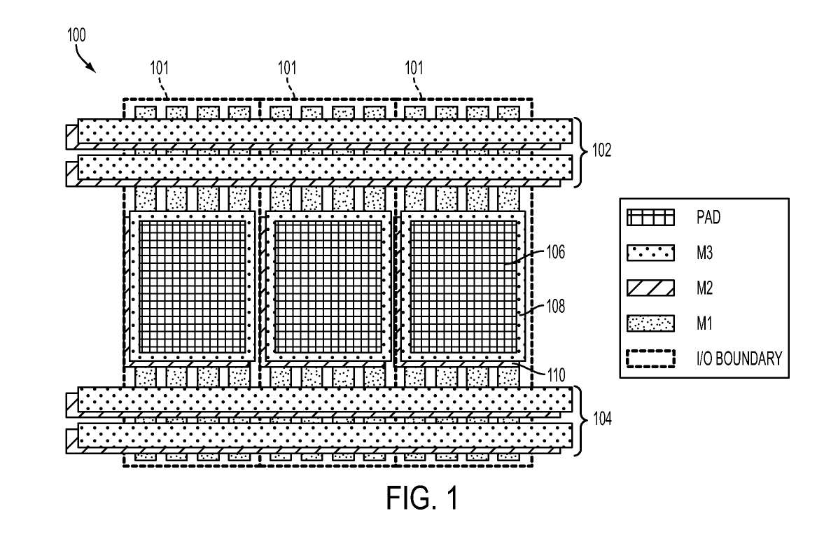

FIG. 1 is a schematic diagram showing an exemplary integrated circuit layout (structure) for an IO cell according to some embodiments. An IO cell electrically interconnects an integrated circuit chip with outside circuitry. The layout 100 includes IO cells 101, a high voltage power supply (VDD) rail bus 102 (i.e., power bus), a low voltage power supply (VSS) rail bus 104 (i.e., ground bus), an IO (contact) pad 106, pad protection areas 108 and 110.

The structure in the layout 101 has multiple metal layers M1, M2, and M3, and the IO pad 106 (additional metal layer) is implemented directly over the top metal layer (in this example, the third metal layer M3). Each IO cell 101 has the IO pad 106 that is used for electrical contact, e.g., wire bonding in packaging. For the sake of simplicity, the substrate and the devices fabricated on the substrate are not shown in the layout 100.

In the layout 100, the IO pad protection areas 108 and 110 are implemented using the same metal layers M2 and M3 as the VDD rail bus 102 and VSS rail bus 104. The first metal layer M1 is used for wiring signal paths and interconnects of various devices and contacts on a substrate, e.g., power signal, ground signal, etc. Because the IO pad protection areas 108 and 110 are in the metal layers M2 and M3 that are also used to implement the VDD rail bus 102 and VSS rail bus 104, there is no need to have additional metal layers, e.g., M4 and M5, for the IO pad protection areas 108 and 110.

In one embodiment, the metal layers for the IO pad protection areas 108 and 110 have a thickness of about 3000 Å. In other embodiments, only one metal layer may be used for the IO pad protection area (e.g., either 108 or 110), or more than two metal layers may be used for the IO pad protection area below the IO pad 106.

In one example, the layout 100 can be implemented using a standard single-poly triple-metal (1P3M) process, without additional metal layers except the IO pad 106. Different metal schemes, e.g., 1P5M, 1P6M, or 2P4M, etc. can be used in different embodiments. The metal layers are interlaced (alternated) with insulation layers, e.g., Inter-Layer Dielectric (ILD), to prevent a short circuit. Vias (now shown) are used for electrical connections among the IO pad 106, different metal layers, and/or devices on the substrate. For example, the IO pad 106 can be electrically connected to any of the metal layers and/or devices on the substrate using a via.

ILD comprises dielectric material to electrically separate closely spaced interconnect lines arranged in several levels (multilevel metallization), e.g., SiO₂ (which has a dielectric constant (k) of approximately 3.9), SiOC (k˜2.7), or other low-k dielectric material (k lower than 3.9) to minimize capacitive coupling between adjacent metal lines.

The IO pad 106 is placed in the middle of each IO cell 101 between the VDD rail bus 102 and the VSS rail bus 104. This is for electrostatic discharge (ESD) protection, and also provides convenient routing for PMOS transistors in the upper part of the IO cell 101 and NMOS transistors in the lower part of the IO cell 101 in some embodiments. The IO pad 106 can directly connect through M3-M1 to IO devices implemented on the substrate below M1, using vias.

If the IO pad 106 and pad protection areas 108 and 110 were placed on top of the VDD rail bus 102 and VSS rail bus 104 in a different layout scheme, it would require additional metal layers. And the layout floor plan can be rearranged so that the IO pad 106 is placed between the VDD rail bus 102 and the VSS rail bus 104 in the IO cell 101 as shown in FIG. 1. By the rearrangement, the same metal scheme can be used for the IO pad protection areas 108 and 110, as the power/ground bus (e.g., metal layers M2 and M3 for the VDD rail bus 102 and the VSS rail bus 104) in the IO cell 101, which does not require additional metal layers. The IO pad 106 is implemented directly over the top metal layer, e.g., M3.

Even though three metal layers (M1, M2, and M3) and the IO pad 106 (another metal layer) are shown in FIG. 1, different number of metal layers can be used in other embodiments. For example, ten metal layers (M1, M2 . . . M10) can be used in another embodiment, where M9 and M10 are used for VDD rail bus 102 and VSS rail bus 104, as well as pad protection areas 108 and 110, with the IO pad 106 implemented directly over the top metal layer M10.

Metal features, such as the metal layers M1, M2, M3, and the IO pad 106, can comprise copper, copper alloy, aluminum, aluminum alloy, any combination thereof, or any other suitable material. The layout 100 including metal features (and insulation layer, a polysilicon layer, or any other general features) may be formed using standard complementary metal-oxide semiconductor (CMOS) processes, e.g., a chemical vapor deposition (CVD), a physical vapor deposition (PVD), photolithography, etching, damascene, etc.

The damascene process includes depositing a dielectric layer, etching the dielectric layer to form openings or trenches, filling the openings or trenches with metallic materials, and performing a chemical mechanical polish (CMP) to remove excess material. The formation of the openings or trenches can involve ashing processes.

A substrate surface is deposited with at least one insulation layer, at least one polysilicon layer and at least one metal layer. The amounts and the stacking order of the insulation layers, polysilicon layers and metal layers depend on the process. For example, the user can choose a process of one poly silicon layer and four metal layers (1P4M), two polysilicon layers and three metal layers (2P3M), and so on. The photolithography and etching processes are used to form the layers and the circuit layout needed. Vias can be formed to electrically connect the IO pad 106 and any of the metal layers or devices on the substrate.

In an exemplary stacked structure using a single-poly three-metal (1P3M) CMOS process, a desired multilayer integrated circuit layout structure is formed, including the polysilicon layer, the first metal layer M1, the second metal layer M2, the third metal layer M3, and insulation (dielectric) layers in between. The third metal layer M3 can be covered with a passivation layer to prevent the integrated circuit layout structure from external impurities and mechanical damage. The material of the passivation layer can include silicon nitride or any other suitable material. The passivation layer is etched out to make opening for the IO pad 106. The IO pad 106 is formed directly over a top metal layer, e.g., M3, through the opening.

The insulation layer, the polysilicon layer, and metal layers can be formed by depositing on a substrate using deposition techniques such as physical vapor deposition (PVD) and chemical vapor deposition (CVD). A photolithography process and an etching process are used to define the geometric size and shape of each layer and vias. The material of the metal layer includes Al, Cu, AlCu alloy, or any other suitable material. By repeating the steps of the thin film process, photolithography process, and etching process to successively form the first metal layer M1, the second metal layer M2, the third metal layer M3, insulation layers, vias that penetrate through different metal layers can be formed for the layout 100.

With damascene processing, the dielectric material is deposited as a blanket film, and is patterned and etched leaving holes or trenches. In single damascene processing, metal, e.g., copper, is then deposited in the holes or trenches surrounded by a thin barrier film resulting in filled vias or wire lines respectively. In dual damascene technology, both the trench and via are fabricated before the deposition of the metal, e.g., copper, resulting in formation of both the vias and wire lines simultaneously, further reducing the number of processing steps.

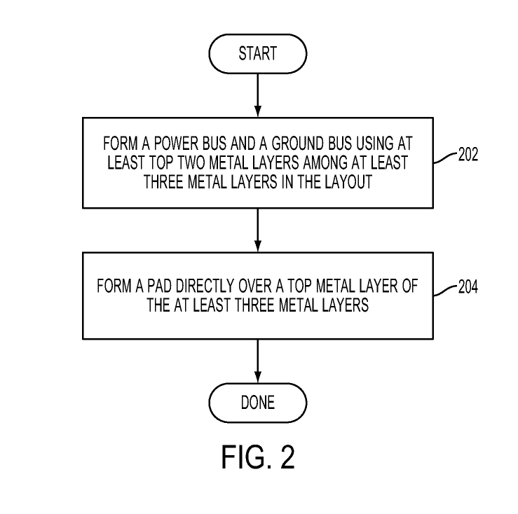

FIG. 2 is a flowchart for a method of forming an IO cell for the exemplary integrated circuit layout in FIG. 1 according to some embodiments. At step 202, a power bus and a ground bus are formed using at least the top two metal layers of at least three metal layers in the layout. At step 204, an IO pad is formed directly over a top metal layer of the at least three metal layers.

In various embodiments, the IO pad is located between the power bus and the ground bus. The IO pad is electrically connected to one of the at least three metal layers or a device on a substrate using a via. An IO pad protection area is formed using the at least top two metal layers of the at least three metal layers in the layout. Insulation layers are formed between metal layers of the at least three metal layers. The insulation layers comprise low-k dielectric material. The top metal layer is the third level metal layer of the integrated circuit layout with a 1P3M scheme.

According to some embodiments, an integrated circuit layout for an Input Output (IO) cell includes at least three metal layers. An IO pad is disposed directly over a top metal layer of the at least three metal layers. At least top two metal layers of the at least three metal layers provide a power bus and a ground bus.

According to some embodiments, a method of forming an Input Output (IO) cell includes forming a power bus and a ground bus using at least the top two metal layers of at least three metal layers in the layout. An IO pad is formed directly over a top metal layer of the at least three metal layers.

A skilled person in the art will appreciate that there can be many embodiment variations of this disclosure. Although the embodiments and their features have been described in detail, it should be understood that various changes, substitutions and alterations can be made herein without departing from the spirit and scope of the embodiments. Moreover, the scope of the present application is not intended to be limited to the particular embodiments of the process, machine, manufacture, and composition of matter, means, methods and steps described in the specification. As one of ordinary skill in the art will readily appreciate from the disclosed embodiments, processes, machines, manufacture, compositions of matter, means, methods, or steps, presently existing or later to be developed, that perform substantially the same function or achieve substantially the same result as the corresponding embodiments described herein may be utilized according to the present disclosure.

The above method embodiment shows exemplary steps, but they are not necessarily required to be performed in the order shown. Steps may be added, replaced, changed order, and/or eliminated as appropriate, in accordance with the spirit and scope of embodiment of the disclosure. Embodiments that combine different claims and/or different embodiments are within scope of the disclosure and will be apparent to those skilled in the art after reviewing this disclosure.

What is claimed is:

1. An integrated circuit layout for an Input Output (IO) cell, comprising:
at least three metal layers; and
an IO pad disposed directly over a top metal layer of the at least three metal layers,
wherein at least top two metal layers of the at least three metal layers provide a power bus and a ground bus.

2. The integrated circuit layout of claim 1, wherein the IO pad is located between the power bus and the ground bus.

3. The integrated circuit layout of claim 1, wherein the IO pad is electrically connected to one of the at least three metal layers using a via.

4. The integrated circuit layout of claim 1, wherein the at least top two metal layers provides an IO pad protection area.

5. The integrated circuit layout of claim 4, wherein the IO pad protection area is located between the power bus and the ground bus.

6. The integrated circuit layout of claim 1, further comprising insulation layers disposed between metal layers of the at least three metal layers.

7. The integrated circuit layout of claim 6, wherein the insulation layers comprise a low-k dielectric material.

8. The integrated circuit layout of claim 1, wherein the IO pad is electrically connected to a device on a substrate using a via.

9. The integrated circuit layout of claim 1, wherein the top metal layer is a third level metal layer of the integrated circuit layout with a single-poly triple-metal (1P3M) scheme.

10. A method of forming an Input Output (IO) cell layout, comprising:
forming a power bus and a ground bus using at least top two metal layers of at least three metal layers in the IO cell layout; and
forming an IO pad directly over a top metal layer of the at least three metal layers.

11. The method of claim 10, wherein forming the IO pad comprises locating the IO pad between the power bus and the ground bus.

12. The method of claim 10, further comprising electrically connecting the IO pad to one of the at least three metal layers using a via.

13. The method of claim 10, further comprising forming an IO pad protection area using the at least a top two metal layers of the at least three metal layers in the layout.

14. The method of claim 10, further comprising forming insulation layers between metal layers of the at least three metal layers.

15. The method of claim 14, wherein the insulation layers comprise low-k dielectric material.

16. The method of claim 10, further comprising electrically connecting the IO pad to a device on a substrate using a via.

17. The method of claim 10, wherein the top metal layer is a third level metal layer of the integrated circuit layout with a single-poly triple-metal (1P3M) scheme.

18. An integrated circuit layout for an Input Output (IO) cell, comprising:
at least three metal layers; and
an IO pad disposed directly over a top metal layer of the at least three metal layers,
wherein at least top two metal layers of the at least three metal layers provide a power bus, a ground bus, and an IO pad protection area, and the IO pad is located between the power bus and the ground bus.

19. The integrated circuit layout of claim 18, wherein the IO pad is electrically connected to one of the at least three metal layers or a device on a substrate using vias.

20. The integrated circuit layout of claim 18, further comprising insulation layers disposed between metal layers of the at least three metal layers, wherein the insulation layers comprise a low-k dielectric material.
